(19) United States
(12) Patent Application Publication
(10) Pub. No.: US 2007/0033386 A1
(43) Pub. Date: Feb. 8, 2007

(54) Computer working environment apparatus

(75) Inventor: Nick Lin, Junghe City (TW)

Correspondence Address: BRUCE H. TROXELL, SUITE 1404, 5205 LEESBURG PIKE, FALLS CHURCH, VA, 22041, US

(73) Assignee: Vantech Software Company

(21) Appl. No.: 11/195,833

(22) Filed: Aug. 3, 2005

(51) Int. Cl. H03F 3/217; G06F 15/177

(52) U.S. Cl. 713/1; 330/251

(57) ABSTRACT

A computer-working-environment apparatus that can be used on and transferred between a plurality of computers. The apparatus comprises: a memory, a computer-working-environment software and one identification code. The computer-working-environment software is stored in the memory, and will be automatically installed on a computer when the computer-working-environment apparatus is connected to the computer for the first time. The identification code is stored in the memory, and the computer-working-environment software installed in the computer needs to verify the identification code from the connected computer-working-environment apparatus to activate the apparatus. In the process, as the computer-working-environment apparatus is connected to the first computer, the computer-working-environment software can store a plurality of data relevant to the first “working environment” as presented by the first computer; subsequently, when the computer-working-environment apparatus is connected to the second computer, the data will be read and then input into the second computer so that the second computer can be operated as in the “working environment” of the first computer.

### FIELD OF THE INVENTION

The present invention is related to a sync device, particularly to one computer transfer computer environment thereof to another in terms of a computer working environment apparatus.

### DESCRIPTION OF PRIOR ART

With the increasing popularity of PCs (personal computers), either desktop PCs or notebook PCs can be found anywhere in our daily lives. Many users have access to at least two computers in their daily lives, often one at home for private use and another at work for business purposes. Businessmen, who often have to work from place to place when traveling for business, often need to use computers to handle certain tasks; as such, many airports and hotels provide computers for businessmen to use. However, as different computers use different operation apparatus and even computers using the same operation apparatus have different personalized settings and user interfaces, making them difficult for most guest users to use, notebook computers have long since become a necessary piece of equipment for most businessmen. Many manufacturers of notebook computers thus look at businessmen as their primary customers, targeting their products at those people who need to use the same computer at different locations.

However, no matter how light and compact a notebook computer is, it still carries some weight and occupies some space, with the technology for its portability having reached a bottleneck. At present, the most portable notebook computer weighs approximately one kilogram, which is not much a burden when compared to the total weight of one's luggage; but as the notebook computer is a delicate electronic device which may be easily damaged if transported with checked-in luggage, it is normally hand-carried by the user, and may thus become a significant burden. In addition, the problem of power supply is another major factor that limits the portability and mobility of the notebook computer. Of course, there are other technologies dedicated to addressing these problems of portability and mobility, for example, there are PDAs (personal digital assistants) of various makes on the market that can meet the user's demand for processing digital tasks on-the-go. Yet the functions of PDAs, no matter how sophisticated they may be, cannot entirely replace those of the computer, so PDAs can, normally, just serve as a supplement to the computer.

On the other hand, aside from the continuous progress in computer technology, the rapid advancement of internet technology is another major factor contributing to the popularity of personal computers. The internet has made it possible for computers to communicate with each other, access each other's data, and make exchanges. For users having access to several computers, however, a problem arises from computer usage. As aforementioned, every computer has its own personalized settings, such as e-mail account settings, “bookmarks”, “history” and “cookies” for web browsers, or different desktops, shortcuts, etc., all of which are interfaces or programs frequently used by the user; thus, in a very literary sense, we can say that such settings are the “working environment” of a computer.

When a user has to use more than one computer, he or she naturally wishes to integrate all the computers different sets of personalized settings into one so that he can always have the same “working environment” when using different computers. But integrating the sets of personalized settings of several computers is not an easy task; for instance, when the user adds a web address to the “bookmark” of the web browser on the first computer, there is no existing technology that can automatically add the web address to the bookmark of the web browser on the second computer, so the user must manually add the web address onto the second computer. Moreover, there are many personalized settings which cannot be added manually, such as the “cookies” stored in the user's computer hard drive by some website servers to identify the individual terminal computer or to record the user's personalized settings of that particular web page, for cookies are one type of personalized settings that cannot be added manually. Thus, personalized settings on the same computer (such as the first computer) can be changed, but implementing these changes one by one on another computer (such as the second computer) can be a cumbersome job, not to mention unworkable when it comes to changes that cannot be manually implemented by the user.

In addition to personalized settings, users often have to process the same files over several computers. Generally speaking, most people save their files in folders that carry the name over different computers, for instance, the most frequently used folder name “My Documents” is the same on every computer. When a user works on the first computer, some of the files may be opened and updated, and when he works on the second computer, some other files may also be opened and updated. In other words, the files in the first and the second computers may have the same name but are in different versions that it will be impossible for you to copy all the files from the first to the second computer (or vice versa) in one go, as it will lead to the overwriting of the newer versions of certain files of the second computer by the older versions of such files in the first computer. How to maintain the files on different computers in the most updated state while preventing newer versions from being overwritten by older ones accidentally is one of the focuses of the present invention.

In sum, as computers and the internet are becoming more and more popular, the major aim of the present invention is to improve the inadequacies of the prior art by integrating several computer “working environments” and files into one so that users having access to several computers may have the same “working environment” over different computers at different locations.

### SUMMARY OF THE INVENTION

The aim of the invention is to provide a solution for users having access to several computers to have the same “working environment” over different computers at different locations.

Another aim of the invention is to provide an alternative solution to the problem of limited portability and mobility of prior art notebook computers.

Still another aim of the invention is to improve the inadequacies of the prior art in terms of the ability (or “inability”) to integrate different “working environments” and files for users having access to several computers.

The present invention provides a computer-working-environment apparatus that can be used on and transferred between a plurality of computers. The apparatus comprises: a memory, a computer-working-environment software and one identification code. The computer-working-environment software is stored in the memory, and will be automatically installed on a computer when the computer-working-environment apparatus is connected to the computer for the first time. The identification code is stored in the memory, and the computer-working-environment software installed in the computer needs to verify the identification code from the connected computer-working-environment apparatus to activate the apparatus. In the process, as the computer-working-environment apparatus is connected to the first computer, the computer-working-environment software can store a plurality of data relevant to the first “working environment” as presented by the first computer; subsequently, when the computer-working-environment apparatus is connected to the second computer, the data will be read and then input into the second computer so that the second computer can be operated as in the “working environment” of the first computer.

Through this computer-working-environment apparatus, the problem of integrating computer “working environments” and files into one for users having access to several computers can be solved. In addition to offering the users the benefit of a highly portable favorite personal computer-working-environment that can be simulated and used on different computers, the present invention can also effectively and substantially synchronize the updating of a plurality of computers, significantly increasing the efficiency of data updating and file integration.

### BRIEF DESCRIPTION OF THE DRAWINGS

The above features of the present invention will be more clearly understood from consideration of the following descriptions in connection with accompanying drawings in which:

FIG. 1 illustrates several computers may be convenient to make a second computer having the same computer working environment as his first computer by means of the computer-working-environment apparatus according to the present invention.

FIG. 2 shows computer working environment while the computer-working-environment apparatus connected with the first computer.

FIG. 3 shows computer working environment while the computer-working-environment apparatus connected with the second computer after fetching the first relevant data group.

### DESCRIPTION OF PREFERRED EMBODIMENTS

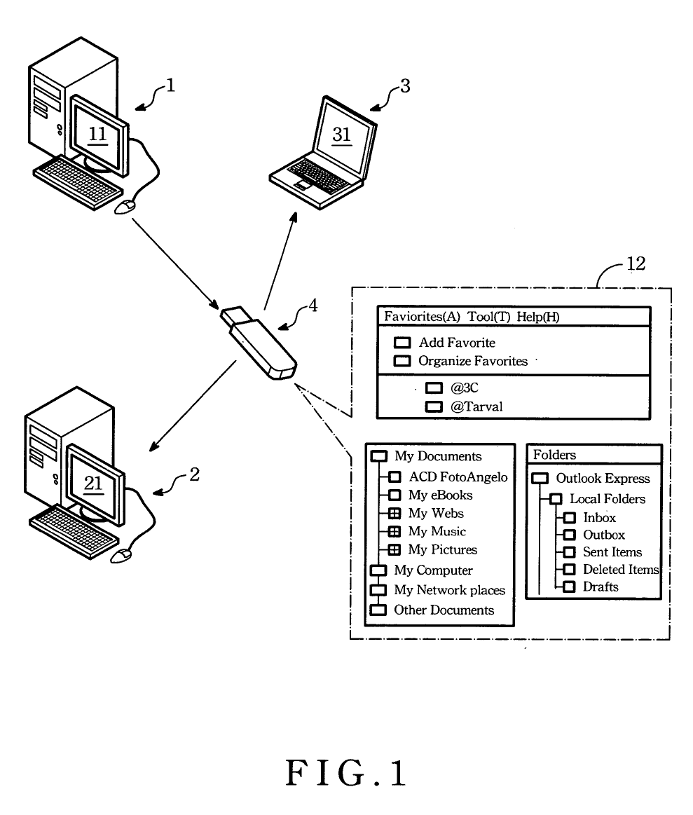

Please refer to FIG. 1 for the present invention's computer-working-environment apparatus, which is designed to be used on and transferred between a plurality of computers. For example, a first computer 1, a second computer 2 and a third computer 3 all of them have different sets of personalized settings, which results in the three computers having three different “working environments”, hereunder referred to as the first “working environment” 11, the second “working environment” 21 and the third “working environment” 31 respectively. If the first computer 1 is the computer most frequently used by the user, the second computer 2 and the third computer 3 can be synchronized to present the first “working environment” 11 with the use of the present invention's computer-working-environment apparatus. In other words, through the present invention's computer-working-environment apparatus 4, the second computer 2 and the third computer 3 can be operated in the first “working environment” 11. The aforementioned first “working environment” 11 comprises relevant “environment” settings, such as the desktop, web browser, e-mail account and other specific files.

The embodiments of computer-working-environment apparatus 4 according to the present invention is not restricted, or limited in anyway but focus on high portability. The apparatus 4 can be selected one from the group consisting of USB pen-drives, SD memory cards, SM memory cards, CF memory cards, XD memory cards, card readers with built in memory, and PDAs. The computer-working-environment apparatus 4 includes a memory chip 41, a computer-working-environment software 42 and an identification code 43. Referring to FIG. 1, a computer-working-environment software 42 is stored in the memory chip 41, and when the computer-working-environment apparatus 4 is connected to any one of computers 1, 2, or 3 for the first time, the computer-working-environment software 42 will be automatically installed in the computer which is connected to the computer-working-environment apparatus 4. Identification code 43 is stored in memory 41, and the computer-working-environment software 42 verifies the identification code 43.

In the process, when the computer-working-environment apparatus 4 is connected to the first computer 1, the computer-working-environment software 42 store a plurality of data relevant to the first “working environment” 11 as presented by the first computer 1 (*for brevity, the phrase, “a plurality of data relevant to the first “working environment” 11”, will hereinafter be referred to as “the first relevant data group 12”).

In one embodiment, the first relevant data group 12 is stored in the memory chip 41 of the computer-working-environment apparatus 4, or, in another embodiment, the first relevant data group 12 is stored in a server 6 through the internet. Subsequently, when the computer-working-environment apparatus 4 is connected to the second computer 2, the first relevant data group 12 will be restored into the second computer 2 so that the second computer 2 can operate in the first “working environment” 11. By the same principle, when the computer-working-environment apparatus 4 is connected to the third computer 3, the first relevant data group 12 is restored into the third computer 3 so that the third computer 3 can also operate in the first “working environment” 11.

As illustrated in FIG. 1, the computer-working-environment apparatus 4 is a medium that carries the computer-working-environment software 42. Only a user has to do is carry the computer-working-environment apparatus 4 having the first-relevant data group 12 to a different computer, which the user work at. After the computer-working-environment software 42 is automatically installed, the first “working environment” 11 of the first computer will be transferred to the computer to be worked and presented as it is. In this transferred “working environment”, all the user's personalized settings such as e-mail account settings, “bookmarks”, “history” and “cookies” for web browsers, desktops, shortcuts, and work-related documents and files will be presented as they are on the first computer 1. In view of this, the present invention certainly provides a solution to the prior art, enabling the user to use the same computer “working environment,” the first “working environment” 11) over different computers

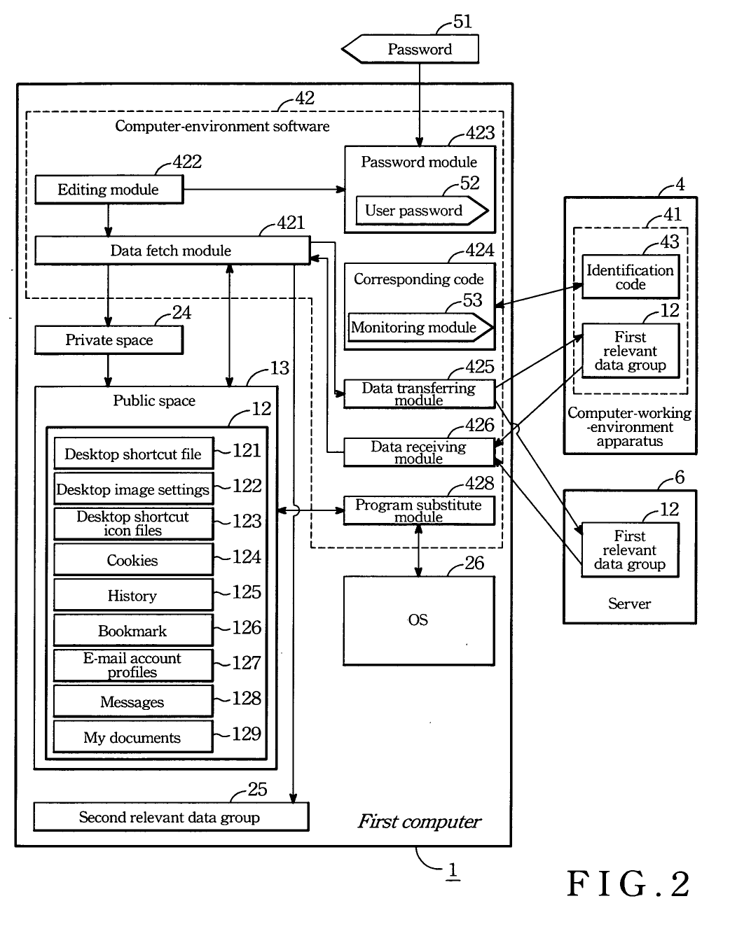

FIG. 2 shows the computer-working-environment apparatus 4 being connected to the first computer 1. As illustrated in FIG. 2, after the computer-working-environment apparatus 4 is connected to the first computer 1, the computer-working-environment software 42 is installed in the first computer 1. The computer-working-environment software 42 comprises a data fetch module 421 to be used for fetching the first relevant data group 12. The first relevant data group 12 includes a desktop image file 121, a desktop shortcut setting file 122 and a desktop shortcut icon file 123 of the first computer 1. The desktop image file 121, desktop shortcut setting file 122 and desktop shortcut icon file 123 are relevant to the desktop settings of the first computer 1. The relevant search paths and target file names for acquiring files are built into the data fetch module 421. In one embodiment, the data fetch module 421 acquires the storage location of the desktop image file 121 from the system registry table therefrom acquiring desktop image file 121. Data fetch module 421 can further acquire the storage location of the desktop folder from the system registry table table, and then scan the desktop folder to acquire the desktop shortcut setting file 122 and the desktop shortcut icon file 123.

Still referring to FIG. 2, which shows that the first relevant data group 12 also comprises a cookie 124, browser history 125 and a bookmark 126 of the web browser of the first computer 1. The cookie 124, the browser history 125 and the bookmark 126 are relevant to the web browser settings of the first computer 1. The relevant search paths and target file names for acquiring the files are built into the data fetch module 421. In one embodiment, the data fetch module 421 acquires the storage locations of the cookie 124, the browser history 125 and the bookmark 126 from the system registry table, and goes on to acquire the cookie 124, the browser history 125 and the bookmark 126.

Please refer to FIG. 2, which shows that the first relevant data group 12 also comprises an e-mail account setting file 127 and at least one message file 128 of the first computer 1. The E-mail account setting file 127 and the message file 128 are relevant to the e-mail account settings of the first computer 1. The relevant search paths and target file names for acquiring the files are built into the data fetch module 421. In one embodiment, the data fetch module 421 acquires the storage locations of the e-mail account setting file 127 and the message file 128 from the system registry table, and goes on to acquire the e-mail account setting file 127 and the message file 128.

The first relevant data group 12 also comprises a “My Documents” folder 129 of the first computer 1, as is shown in FIG. 2. Considering that many users customarily save frequently used word files and data in the My Documents folder 129, one embodiment of the present invention is to set “the data fetch module 421 acquiring and saving data fetch module 421” as a default action. In other embodiments, an editing module 422 can be used to change the default action of data fetch module 421 in order to specify the relevant path and name of the files to be acquired and saved.

Noticed that the aforementioned first relevant data group 12 of the first “working environment” 11, such as the desktop file 121, the desktop shortcut setting file 122, the desktop shortcut icon file 123, the cookies 124, the browser history 125, the 126, the e-mail account setting file 127, the e-mail folder 128, and the My Documents folder 129, are, respectively, stored in the first computer 1 by various paths according to operating system and program configurations of the first computer 1. To facilitate the subsequent illustrations, the area for first relevant data group 12 stored is called Public Space 13. Public Space 13 contains the individual active file paths of the first relevant data group 12.

In FIG. 2, computer-working-environment software 42 also further comprises a password module 423 and a monitoring module 424. Accordingly, the computer-working-environment apparatus 4 itself though does not possess operation functions as that of a conventional computing provided, it, however, can make a computer be transformed into the first “working environment” 11 as user customarily used if and only if the computer is connected with the computer-working-environment apparatus 4.

Thus, to enhance the security of the computer-working-environment apparatus 4 and to prevent the personal data of the user from being stolen, a password module 423 and a monitoring module 424 are used according to the present invention. When the computer-working-environment apparatus 4 is connected to the computer, the password module 423 will display a dialog box to request a password 51 to be inputted. If the password 51 keyed matches with the predetermined user password 52, the computer-working-environment software 42 will active. In one embodiment of the present invention, the password module 423 also provides functions of password editing and hint. By means of an editing module 422, the user can modify the user password 52 and/or the hint for reminding user password 52.

Monitoring module 424 is used to monitor the identification code 43 in the computer-working-environment apparatus 4 with the corresponding code 53, which is recorded in the computer when the computer-working-environment software 42 is installed. If the identification code 43 matches with the corresponding code 53, the computer can be as operated at the “working environment” as the first computer 1. If the computer-working-environment apparatus 4 is disconnected with the computer, the “working environment” will be lost form the computer.

After the data fetch module 421 acquires the first relevant data group 12 from the first computer 1, the first relevant data group 12 is stored in the memory chip 41 of the computer-working-environment apparatus 4 by using a data transferring module 425. Or, in another embodiment, the first relevant data group 12 is stored in the server 6 through the internet.

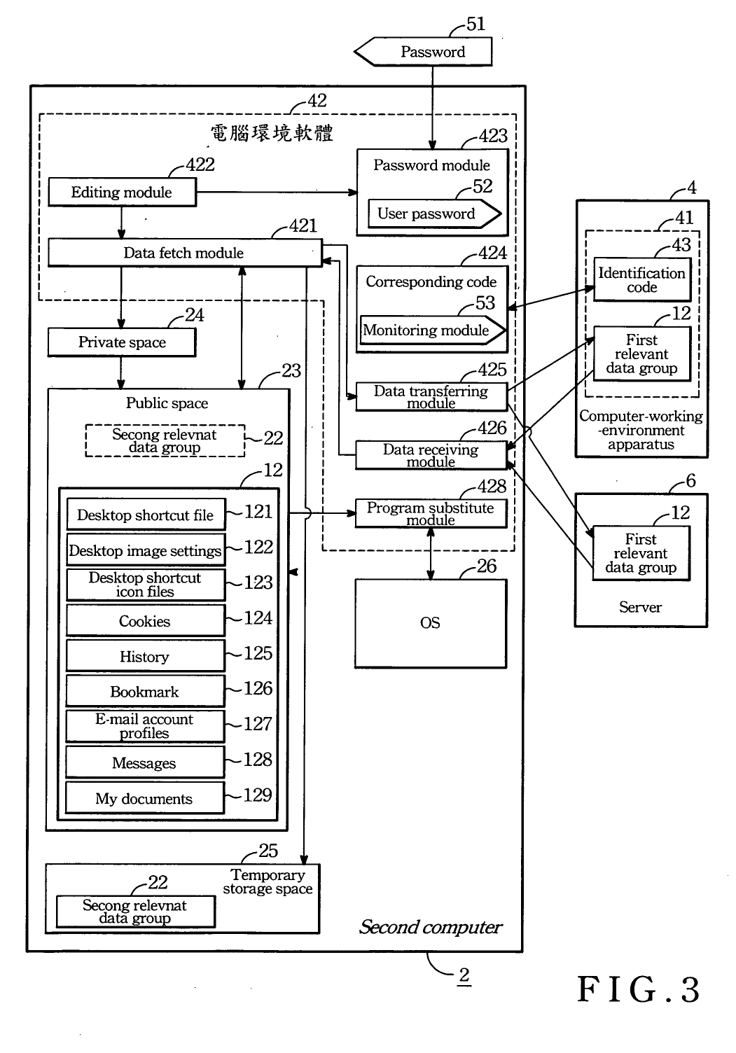

Please refer to FIG. 3, which shown the computer-working-environment apparatus in FIG. 1 as being connected to the second computer. As is illustrated in FIG. 3, after the computer-working-environment apparatus 4 get the first relevant data group 12, the computer-working-environment software 42 is installed in the second computer 2. The second computer 2 represents a computer that is temporarily or less frequently used.

As is illustrated in FIG. 1, the second computer 2 originally has a default second “working environment” 21; a plurality of data relevant to the second “working environment” 21 (hereafter referred to as “the second relevant data group 22”), which is illustrated in FIG. 3. The second relevant data group 22 is stored in the public space 23, where the public space 2 comprises the paths of personalized file settings of the second computer 2, such as e-mail account settings, “bookmarks” settings, “browser history,” and “cookies” for web browsers, or desktops, shortcuts, and work-related documents and files.

When the computer-working-environment apparatus 4 is connected to the second computer 2, the password module 423 and the monitoring module 424 are used to check as before to prevent personal data from being stolen. When the computer-working-environment software 42 is activated, the first relevant data group 12, which is relevant to the first “working environment” 11, is read, as shown in FIG. 3, by a data receiving module 426. Thereafter, the first relevant data group 12 is being transferred to a private space 24 of the second computer 2. The private space 24 and a temporary storage space 25 are created by the computer-working-environment software 42. The data fetch module 421 then transfers the second relevant data group 22 stored at the public space 23 to a temporary storage space 25. Thereafter, the user can operate the second computer 2 as he is work in the first “working environment 11.”

After the user finishes his work on the second computer 2 and prepares to remove the computer-working-environment apparatus 4, a virtual mode or a sync mode can be selected according to whether the first “working environment” 11 is removed or not. In a “virtual mode,” a removal procedure is made. Because many changes might have occurred to the first relevant data group 12 stored in the public space 23 while the user was working, means the first relevant data group 12 is updated. The computer-working-environment software 42 then executed and make the data fetch module 421 to acquire the first relevant data group 12 and uses a data transferring module 425 to transfer the first relevant data group to the memory chip 41 or the server 6 for storage in order to maintain the most updated version of the first “working environment” 11 in the computer-working-environment apparatus 4. In the removal procedure, the computer-working-environment software 42 will restore the second relevant data group 22 in a temporary storage space 25 into the public space 23 so that the second computer 22 can be returned to its original second “working environment” 21, please see FIG. 1. It will also delete the private space 24, the temporary storage space 25 and all the data established by the user so that other subsequent users cannot use the aforementioned personal data when working on the second computer 2. This virtual mode is suitable for occasions when the user is traveling and needs to use a public or borrowed computer temporarily.

In a “sync mode,” the removal procedures do not restore the second relevant data group 22 into public space 23 so that the second computer 2 can still operate in the first “working environment” 11 after the computer-working-environment apparatus 4 is removed. This sync mode is suitable for users who own several computers such as the first computer 1, the second computer 2 and the third computer 3 in FIG. 1. Since all belong to the same user and there is no worry about personal data being stolen; this sync mode can also effectively solve the problems of the prior art as described above in terms of the difficulty in integrating various computer “working environments” and files for users having several computers. In the sync mode, the private space 24, the temporary storage space 25 and all the data within can be optional removed.

As shown in FIG. 3, the virtual mode and the sync mode can be selected from dialog box, which is set by a mode selection module 472 in the computer-working-environment software 42. In another embodiment, the mode selection module 427 offers the selection of a “dummy mode” too. When the dummy mode is selected, the computer-working-environment software 42 does not launch its synchronizing functions, but allows the user to change some settings.

When the user goes back to work on the first computer 1, connecting the computer-working-environment apparatus 4 to the first computer 1 he or she will be allowed to choose among the aforementioned virtual mode, sync mode or dummy mode. Of course, when the aforementioned first computer 1 is among the user's most frequently used computers, the user can normally select the sync mode to maintain the most updated first “working environment” 11 on the first computer 1.

A point worthy of mentioning is that the computer-working-environment software 42 of the present invention also has a substitute program search function. For instance, if the web browsers in the first computer 1 and the second computer 2 are different as is the case when the second “working environment” 21 uses Microsoft Internet Explorer and the first “working environment” 11 uses Netscape, then, taking FIG. 3 as an example where the desktop shortcut file 122 represents the shortcut for launching the Netscape program, the computer-working-environment software 42 can launch the substitute program search function to direct this desktop shortcut file 122 to the Microsoft Internet Explorer program in the second computer 2.

The substitute program search function of computer-working-environment software 42 can be further illustrated as follows: if the e-mail software in the second computer 2 and the first computer 1 are different as is the case when the second “working environment” 21 uses Outlook and the first “working environment” 11 uses Outlook Express, then, taking FIG. 3 as an example where a message file 128 has been launched in its original first “working environment” 11 by Outlook Express, the computer-working-environment software 42 will launch the substitute program search function to open the message file 128 in Outlook as the second computer does not have the Outlook Express software.

The aforementioned substitute program search function is realized by having a program substitute module 428 in the computer-working-environment software 42. As shown in FIG. 3, the program substitution module 428 makes a comparison between the application programs for all the data and files in the first relevant data group 12 and those stored in the OS 26 in the second computer 2, and carries out the aforementioned program substitution action according to a default substitution guideline list.

Briefly, the present invention certainly provides a solution for users to use the same computer-working-environment to handle tasks over different computers at different locations. The present invention is a more effective alternative solution to the prior art concerning the portability of notebook computers. Through the computer-working-environment apparatus, the problem of the prior art concerning the difficulty in integrating computer “working environments” and files for users having access to several computers can be improved. Therefore, in addition to offering the benefit of high portability for users to simulate a familiar set of computer-working-environment settings on different computers, the present invention can synchronize and integrate the files and data of a plurality of computers more effectively and efficiently.

As is understood by a person skilled in the art, the foregoing preferred embodiment of the present invention is an illustration of the present invention rather than limiting thereon. It is intended to cover various modifications and similar arrangements included within the spirit and scope of the appended claims, the scope of which should be accorded the broadest interpretation so as to encompass all such modifications and similar structure.

What is claimed is:

1. A computer-working-environment apparatus, comprising:
a memory chip;
a computer-working-environment software stored in said memory chip, for installed in a computer which connects with said computer-working-environment apparatus; and
an identification code stored in said memory chip as a key of launching a computer-working-environment of a computer which connects with said computer-working-environment apparatus and;
when said computer-working-environment apparatus connected with a first computer, said computer-working-environment software fetches a first relevant data group of said first computer and then stores into said computer-working-environment apparatus, thereafter said first relevant data group will be loaded by said computer-working-environment software of a second computer which connects with said computer-working-environment apparatus.

2. The computer-working-environment apparatus according to claim 1 wherein said first relevant data group comprises a desktop image file of said first computer.

3. The computer-working-environment apparatus according to claim 1 wherein said first relevant data group comprises desktop shortcut setting file of said first computer.

4. The computer-working-environment apparatus according to claim 1 wherein said first relevant data group comprises desktop shortcut icon file of said first computer.

5. The computer-working-environment apparatus according to claim 1 wherein said first relevant data group comprises cookies, browser history, and bookmark of said first computer.

6. The computer-working-environment apparatus according to claim 1 wherein said first relevant data group comprises e-mail account setting file of said first computer.

7. The computer-working-environment apparatus according to claim 1 wherein said first relevant data group comprises an e-mail folder of said first computer.

8. The computer-working-environment apparatus according to claim 1 wherein said first relevant data group comprises My Documents folder of said first computer.

9. The computer-working-environment apparatus according to claim 1 wherein said computer-working-environment software comprises a data fetch module for fetching said first relevant data group.

10. The computer-working-environment apparatus according to claim 1 wherein said computer-working-environment software comprises a virtual mode and a sync mode selection mode for user to select one from them.

11. The computer-working-environment apparatus according to claim 10 when said sync mode is selected, an original working environment of said second computer will be overwritten by said first relevant data group.

12. The computer-working-environment apparatus according to claim 10 when said virtual mode is selected, an original working environment of said second computer is temporary replaced by said first relevant data group and said original working environment of said second computer will be recovered when said “working environment” apparatus is removed from said second computer.

13. The computer-working-environment apparatus according to claim 1 wherein said first relevant data group is stored into said memory chip by means of said working environment” software.

14. The computer-working-environment apparatus according to claim 1 wherein said first relevant data group is stored into a server by means of said working environment” software through internet or intranet.

15. The computer-working-environment apparatus according to claim 1 wherein said working environment” software comprises a module for persistently monitoring said identification code.

16. The computer-working-environment apparatus according to claim 1 wherein said “working environment” software comprises a password module for check the user identification, and said “working environment” software activate only if the user inputs a correct password.

17. The computer-working-environment apparatus according to claim 1 wherein said “working environment” software comprises a data transferring module to transfer updated first relevant data group to the memory chip of the computer-working-environment apparatus.

18. The computer-working-environment apparatus according to claim 1 wherein said “working environment” software comprises a substitute program search module to search a relevant application program from the second computer while is desired to execute an application from the first relevant data group but said second computer does not meet.
